(19) United States
(12) Patent Application Publication
(10) Pub. No.: US 2008/0197764 A1
(43) Pub. Date: Aug. 21, 2008

(54) Electroluminescence Light Source

(75) Inventors: Helmut Bechtel, Roetgen (DE); Horst Greiner, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/913,876

(22) PCT Filed: May 3, 2006
(86) PCT No.: PCT/IB2006/051385

§ 371 Date: Nov. 8, 2007

(30) Foreign Application Priority Data
May 12, 2005 (EP) 05103973.3

(51) Int. Cl. H01L 51/00

(52) U.S. Cl. 313/499

(57) ABSTRACT

Electroluminescence light source having a transparent substrate (2), an electroluminescent layer structure for emitting light throughthe substrate, a first light outcoupling layer (3) arranged between substrate and electroluminescent layer structure for producing a non-uniform angular distribution of the light upon entry of the light into the substrate (2), and a second light outcoupling layer (1) arranged above the substrate (2) when viewed in the direction of propagation of light (7), with a surface structure adapted to the non-uniform angular distribution of the light for the effective light outcoupling from the electroluminescence light source.

The invention relates to electroluminescence light sources with layers for improving the light outcoupling.

An electroluminescence light source (EL light source) composed of a multiplicity of thin layers (EL layer structure) applied on a substrate and having an electroluminescence layer (EL layer) for emitting light is known. A typical structure comprises a substrate, an electrically conductive layer ITO (Indium Tin Oxide) applied on it as a transparent electrode (anode), an electroluminescent layer with a light emitting material and an electrode (cathode) made of a metal, preferably a metal with a low work function. One generally differentiates between bottom emitters (emission through a transparent substrate) and top emitters (emission to the sides facing away from the substrate through a transparent encapsulation device). In the case of top emitters the substrate can also be non-transparent.

A problem of electroluminescence light sources is the low degree of outcoupling of the light produced in the EL layer from the electroluminescence light source. The causes for it are the multiple transitions occurring along the optical path from the EL layer to the exit of the EL light source from an optically denser medium (refractive index n₂) to an optically thinner medium (refractive index n₁ with 1≦n₁<n₂). At the boundary surface between two such media the light is totally reflected if the angles of incidence on the boundary surface are larger than an angle α=arc sin (n₁/n₂). Here, the angle of incidence is the angle between the direction of propagation of the ray of light and the normal to the boundary surface, also referred to as surface normal.

Outcoupling losses due to total reflection occur in the case of emission of the light from the transparent substrate, for example glass, into air as well as in the case of emission of the light from the transparent electrode into the substrate. The transition of the light emitted almost isotropically by the EL layer into the transparent electrode is less crucial as the refractive indices of these layers are mostly very similar. Due to total reflection the outcoupling losses of an electroluminescence light source lead to an outcoupling efficiency of ≦26% of the light originally produced in the EL layer if no additional improvement measures are taken.

Document U.S. 2005/0007000 discloses a multiplicity of possible layers for improving the light outcoupling (light outcoupling layer), for example, volume diffuser layers, surface diffuser layers, layers with a micro-structured surface, anti-reflection layers and light outcoupling layers, which comprise two sub-layers with a common rough or micro-structured surface. These layers can be applied between a transparent electrode and a transparent substrate and/or in the light emission direction on the substrate. As the available electroluminescence light sources show a light outcoupling substantially below 50%, there is a constant need for an improved light outcoupling.

It is therefore an object of this invention to provide an electroluminescence light source with improved light outcoupling.

This object is achieved by an electroluminescence light source having a transparent substrate, an electroluminescent layer structure for emitting light through the substrate, a first light outcoupling layer arranged between substrate and electroluminescent layer structure for producing a non-uniform angular distribution of the light upon entry of the light into the substrate, and a second light outcoupling layer arranged above the substrate when viewed in the direction of propagation of light, with a surface structure adapted to the non-uniform angular distribution of the light for the effective light outcoupling from the electroluminescence light source. Here, a non-uniform angular distribution is an angular distribution deviating from a cosine distribution.

In the state of the art it is not considered that for an optimized light outcoupling, the structure of the second light outcoupling layer must be adapted to the distribution of the angles of incidence. The distribution of the angles of incidence on the boundary surface between substrate andair depends very essentially on whether an additional first light outcoupling layer is present between a transparent electrode and a transparent substrate, which layer influences the angular distribution (angle between direction of propagation of the rays of light and the layer normal) of the light. With the generation of a defined angular distribution of the light in the substrate and a surface structure of the second light outcoupling layer which is optimized for this angular distribution, a better luminous efficiency (number of light quanta outcoupled from the EL light source relative to the number of light quanta produced in the EL layer) is achieved than in EL light sources with one or more light outcoupling layers not tuned to each other. In the case of light outcoupling layers which are not tuned to each other, a first light outcoupling layer can improve the light incoupling into the substrate, without an improved light outcoupling from the EL light source being obtained.

In this connection, it is favorable if the non-uniform angular distribution has a maximum and an angle range of ±15 degrees around said maximum comprises more than 70% of the light, preferably more than 80% of the light, particularly preferably more than 90% of the light. The more light is coupled into the substrate, whose angles of incidence vary essentially only in a narrow range, the more optimally the second light outcoupling layer can be adapted to the angular distribution.

Here, an electroluminescence light source is favorable in which the maximum of the non-uniform angular distribution lies at an angle larger than 45 degrees, preferably larger than 60 degrees, particularly preferably larger than 75 degrees. Effective light-outcoupling surface structures of the second light outcoupling layer can be produced particularly well for rays of light which enter the substrate at a large angle. Here, the angle between the direction of propagation of the light and the surface normal of the boundary surface between substrate and first light outcoupling layer is denoted as light entry angle.

A thickness H₂ of the first light outcoupling layer between 100 nm and 10 μm is favorable for producing a non-uniform angular distribution.

It is further favorable if the first light outcoupling layer comprises at least a first material and a second material.

It is particularly favorable if the first material has a refractive index n₁, the second material a refractive index n₂ and the difference between the refractive indices n₁ and n₂ lies between 0.1 and 2.5. Thus, the two materials differ sufficiently well optically to have an effect on the angular distribution of the light.

In a preferential embodiment, the first material is arranged in the second material essentially in a periodic structure of a multiplicity of structural elements in a plane parallel to the surface of the first light outcoupling layer, which structural elements are designed as spatial bodies, comprising spherical, cylindrical, pyramidal, cubical or ellipsoid bodies. By this periodic and hence grid-like structure, the light incoupling into the substrate can be managed more effectively and in a more defined manner than in the case of a scattering layer with statistically distributed particles. The produced angular distribution of the light in the substrate can also be varied more specifically than, for example, in a scattering grid, which couples the light into the substrate at smaller angleson average .

In this connection, it is favorable if the structural elements, when viewed in the direction of propagation of light, have a height H₁ and the thickness H₂ of the first light outcoupling layer has a value between H₁ and 10*H₁.

For effective light outcoupling into the substrate, it is particularly favorable that at a total number N of structural elements a distance aᵢ between two neighboring structural elements can deviate from an average distance a₀ and the distribution n(aᵢ) of the distances aᵢ fits the formula

$$n ( {a}_{i} ) = \frac{N}{{a}_{i} s \sqrt{2 π}} exp [ - \frac{{ln}^{2} ( {a}_{i} / {a}_{0} )}{2 {s}^{2}} ]$$

wherein 0<s<0.4. The light outcoupling into the substrate can be additionally increased by this specific deviation from the strict periodicity in an ideal grid.

For the outcoupling of light with a non-uniform angular distribution, surface structures of the second light outcoupling layer comprising square pyramidal structures, triangular pyramidal structures, hexagonal pyramidal structures, ellipsoidal dome structures or cone structures are particularly preferable.

In this connection, it is particularly favorable if the height Hᵣ of the surface structure of the second light outcoupling layer in the direction of propagation of light is larger than 10 μm and smaller than 5-fold the substrate thickness.

It is also particularly favorable if the second light outcoupling layer has a refractive index larger than or equal to that of the substrate, whereby total reflection at the boundary surface between substrate and second light outcoupling layer during light emergence from the substrate is avoided.

These and other aspects of the invention are apparent from and will be elucidated with reference to the embodiments described hereinafter, though the invention should not be considered as limited to these.

In the drawings:

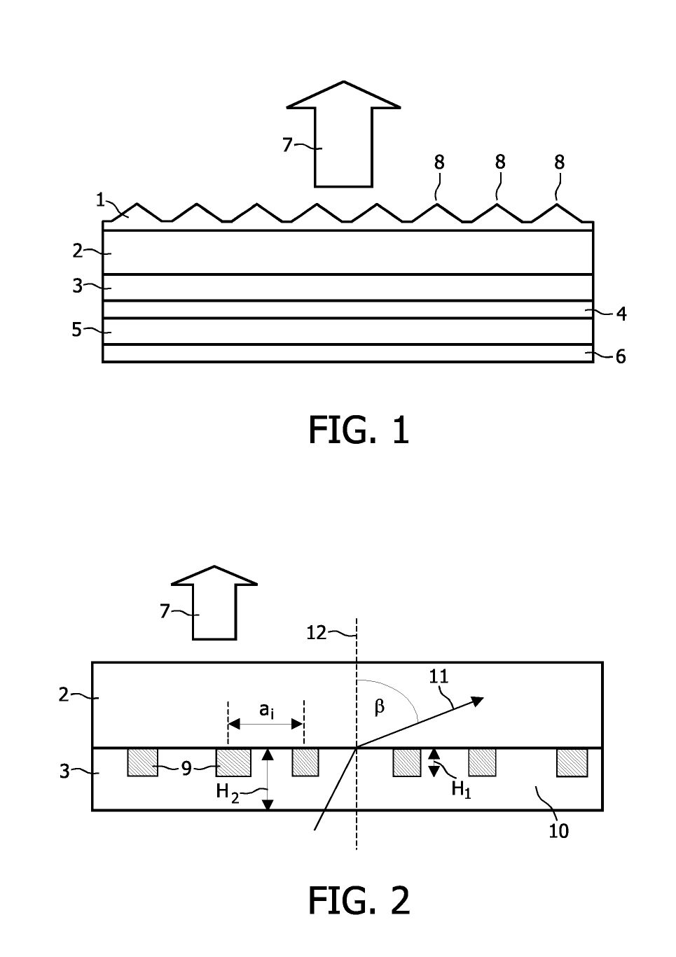

FIG. 1 shows a layer structure of an electroluminescence light source in accordance with the invention

FIG. 2 shows a first light outcoupling layer as a grid-like structure.

What is referred to as a bottom emitting electroluminescence light source generally comprises a layer structure of an organic or inorganic electroluminescent layer 5 (EL layer) applied on a planar transparent substrate 2, for example, borosilicate glass (refractive index 1.45), quartz glass (refractive index 1.50) or PMMA (refractive index 1.49), which electroluminescent layer is arranged between a transparent electrode 4 and an at least partly reflecting electrode 6, see FIG. 1. The EL layer can also be composed of several sub-layers. In organic EL layers, an electron supplylayer of a material with a low work function can be arranged between the electrode 6, typically the cathode, and the EL layer 5 and between the electrode 4, typically the anode, and the EL layer 5 additionally a hole transport layer can be arranged. In a bottom emitting light source, the light 7 reaches the viewer through the substrate.

The transparent electrode 4 can comprise, for example, p-doped silicon, Indium-doped Tin Oxide (ITO) or Antimony-doped Tin Oxide (ATO). It is also possible to produce the transparent electrode from an organic material with particularly high electrical conductivity, for example, Poly (3,4 ethylene dioxythiophene) in polystyrene sulfonic acid (PEDT/PSS, Baytron P from the company HC Starck). Preferably, the electrode 4 comprises ITO with a refractive index between 1.6 and 2.0. The reflecting electrode 6 itself can be reflecting, for example of a material like aluminum, copper, silver or gold, or can additionally have a reflecting layer structure. If, viewed in the direction of light beam 7, a reflecting layer or layer structure is arranged below the electrode 6, the electrode 6 can also be transparent. The electrode 6 can be structured and comprise, for example, a multiplicity of parallel strips ofthe conductive material or conductive materials. Alternatively, instead of being structured, the electrode 6 may be designed as a plane.

The electroluminescence light source in accordance with the invention additionally comprises a first light outcoupling layer 3 between the transparent electrode 4 and the transparent substrate 2, in order to couple the light 11 emerging from the transparent electrode 4 into the substrate 2 with a non-uniform angular distribution n (β), wherein β denotes the angle between the direction of propagation of the light 11 and the perpendicular 12 (layer normal) to the boundary surface between first light outcoupling layer 3 and substrate 2, see FIG. 2. If the angular distribution n(β) of the light incoupled into the substrate 2 is sufficiently non-uniform, that is deviating from a cosine distribution, a further second light outcoupling layer 1 arranged on the substrate 2 at the boundary surface to air and having a surface structure 8 specially adapted to the special angular distribution n(β) produced by the first light outcoupling layer 2, leads to an improvement of the outcoupled quantity of light in comparison to an EL light source without light outcoupling layers 3 and 1 or to an EL light source with one or more light outcoupling layers not matched to each other.

The surface structure 8 of the second light outcoupling layer 1, which surface structure is adapted to the angular distribution of the light in the substrate 2 produced by the first light outcoupling layer 2, comprises in this case square pyramidal structures, triangular pyramidal structures, hexagonal pyramidal structures, ellipsoidal dome structures and/or cone structures.

Such structured layers can be manufactured, for example, by injection molding methods and can be laminated on the substrate or directly applied on the substrate by thin film and lithography processes. Transparent substrates can be manufactured having refractive indices between 1.4 and 3.0. For the second light outcoupling layer, a favorable material has a refractive index larger than or equal to the refractive index of the substrate, in order to avoid total reflection at the boundary surface between second light outcoupling layer and substrate. A material with the same refractive index as the substrate is preferred in order to keep the refractive index difference to air as small as possible to minimize the portion of the light which is reflected at the boundary surface to air. Suitable materials for the second light outcoupling layer are, for example, quartz glass (n=1.54), plexiglass (PMMA, n=1.49) or other plastics with similar refractive indices, for example, PMMI (n=1.53). Preferred surface structures, viewed in the direction of propagation of light, have a height larger than 10 μm and less than 5-fold the substrate thickness.

First light outcoupling layers for producing a non-uniform angular distribution of the light outcoupled into the substrate can comprise layers with a local variation of the refractive index or layers of a matrix material with regularly or irregularly arranged centers in the matrix material for the refraction of light, light scattering or light reflection at these centers. Such centers can be, for example, air inclusions, defects or phase boundaries in the matrix material or particles in the matrix material or structures of materials having a higher and/or lower refractive index than the matrix material or having a reflecting surface or other centers with similar effect.

First light outcoupling layers can be produced, for example, by thin film processes like vapor deposition or sputtering, also in combination with masking, lithography and/or etching processes for structuring the first and/or second material or by wet-chemical methods, such as so-termed spin coating with a suspension having statistically distributed particles. The first light outcoupling layer 3 can also comprise two or more sub-layers with different material properties. It is favorable if the thickness H₂ of the second light outcoupling layer ranges between 100 nm and 10 μm.

In an embodiment, the light outcoupling from an electroluminescence light source is optimized, which light source comprises a light outcoupling layer 3 as a scattering layer of a second material 10 with statistically distributed light-reflecting or refractive particles of at least one first material 9, and a second light outcoupling layer 1, which, as a surface structure 8, has an essentially planar surface with channels having steep side walls. A first light outcoupling layer with reflecting and/or scattering particles produces a non-uniform angular distribution n(β) of the outcoupled light with predominantly small propagation angles β of the light 11 in the substrate 2, as the probability of forward scattering, viewed in the direction of propagation of light 7, at suitable particle parameters like, for example, size and number, increases with the optical path length in the second light outcoupling layer. To make sure that the light with small propagation angles β in the substrate is not subject to total reflection at the boundary surface to air, the surface structure of the first light outcoupling layer should have large planar areas perpendicular to the direction of propagation of light 7. Effective outcoupling of the part of the light having propagation angles larger than the critical angle is brought about by the channels between the planar areas, the side faces of the channels having a suitable depth and including an angle with the layer normal of the substrate in the range between 20 and 30 degrees. A suitable depth of such channels is obtained if the projected surface of all side faces, viewed in the direction of propagation of the rays of light with a large propagation angle β, is clearly larger than the projected surface of the planar areas.

Effective light outcoupling from the first light outcoupling layer as a scattering layer by means of refractive effects into the substrate can favorably be achieved if the values of the refractive indices of the first and second material vary by an amount between 0.1 and 2.5. Suitable materials with a high refractive index are, for example, titanium dioxide (n=2.52-2.71), lead sulfide (n=3.90), diamond (N=2.47) or zinc sulfide (n=2.3). Materials with a low refractive index are, for example, quartz glass (n=1.46), magnesium fluoride (n=1.38), or PMMA (n=1.49). Metals are, for example, suited as materials for a corresponding scattering layer by means of reflecting effects.

In a preferential embodiment, the first light outcoupling layer 3 comprises a first material 9, which is arranged in the second material, essentially in a periodic structure of a multiplicity of structural elements, in a plane parallel to the surface of the second light outcoupling layer 3, the structural elements being designed as spatial bodies, see FIG. 2. In this case, the structural elements can be arranged, as shown in FIG. 2, in a grid-like manner at the boundary surface between first light outcoupling layer 3 and substrate 2 or within the first light outcoupling layer 3. The periodic structure represents an optical grid, whose properties can be adapted, by a person skilled in the art varying the periodic structure, to the wavelength of the light emitted by the EL layer, to the layer structure and to the optical properties of the substrate. In the preferential embodiment, the periodic structure having a height H₁ of the structural elements of a first material 9, a distance aᵢ between neighboring structural elements and a thickness H₂ of the first light outcoupling layer, is selected in such a way that an angular distribution n(β) of the outcoupled light with predominantly large propagation angles β larger than 45 degrees is produced in the substrate 2. Effective outcoupling can particularly favorably be achieved if the thickness H₂ of the first light outcoupling layer 3 lies between the height of the structural elements H₁ and 10*H₁. In the embodiment shown in FIG. 2, the structural elements have cylindrical bodies. For achieving effective light outcoupling, the structural elements can, however, also comprise spherical, pyramidal, cubical, ellipsoidal or other bodies. Likewise, the distance between neighboring structural elements does not need to be strictly periodical, but can vary easily around an average distance a₀. A particularly favorable distance for the light outcoupling is aᵢ, which in accordance with the following distribution n(aᵢ) varies around an average distance a₀:

$$n ( {a}_{i} ) = \frac{N}{{a}_{i} s \sqrt{2 π}} exp [ - \frac{{ln}^{2} ( {a}_{i} / {a}_{0} )}{2 {s}^{2}} ]$$

wherein 0<s<0.4.

To ensure that the light having large propagation angles β in the substrate 2 is not subject to total reflection at the boundary surface to air, the surface structure 8 of the second light outcoupling layer 1, which is adapted to a non-uniform angular distribution with a maximum at large angles, essentially should not have planar areas parallel to the surface of the substrate 2. For example, the side faces of pyramidal structures should include a small angle between side face and layer normal of the substrate, in order to outcouple light with large propagation angles β directly to air without total reflection at the surface of the second light outcoupling layer.

An example of embodiment of the electroluminescence light source in accordance with the invention comprises a first light outcoupling layer for producing a non-uniform angular distribution of the light when the light enters into the substrate, wherein the thickness H₂ of the first light outcoupling layer amounts to 700 nm, the refractive indices n₁ and n₂ of the first and second materials of the first light outcoupling layer amount to 1.42 and 1.94, respectively, the height H₁ of the structural elements in the first light outcoupling layer amounts to 220 nm and the average distance a₀ between the structural elements amounts to 650 nm.

The embodiments explained by means of the Figures and the description only represent examples for improving the light outcoupling from an electroluminescence light source and should not be construedas a limitation of the patent claims to these examples. Alternative embodiments are also possible for those skilled in the art, which embodiments are likewise covered by the scope of protection of the patent claims. The numbering of the dependent claims should not imply that other combinations of the claims do not represent favorable embodiments of the invention.

1. An electroluminescence light source having a transparent substrate (2), an electroluminescent layer structure for emitting light through the substrate, a first light outcoupling layer (3) arranged between substrate and electroluminescent layer structure for producing a non-uniform angular distribution of the light upon entry ofthe light into the substrate (2), and a second light outcoupling layer (1) arranged above the substrate (2) when viewed in the direction of propagation of light (7), with a surface structure adapted to the non-uniform angular distribution of the light for the effective light outcoupling from the electroluminescence light source.

2. An electroluminescence light source as claimed in claim 1, characterized in that the non-uniform angular distribution has a maximum and an angle range of ±15 degrees around said maximum comprises more than 70% of the light (11), preferably more than 80% of the light (11), particularly preferably more than 90% of the light (11).

3. An electroluminescence light source as claimed in claim 1, characterized in that the maximum of the non-uniform angular distribution lies at an angle larger than 45 degrees, preferably larger than 60 degrees, particularly preferably larger than 75 degrees.

4. An electroluminescence light source as claimed in claim 1, characterized in that the first light outcoupling layer (3) has a thickness H₂ between 100 nm and 10 μm.

5. An electroluminescence light source as claimed in claim 1, characterized in that the first light outcoupling layer (3) comprises at least a first material (9) and a second material (10).

6. An electroluminescence light source as claimed in claim 5, characterized in that the first material (9) has a refractive index n₁, the second material (10) a refractive index n₂ and the difference between the refractive indices n₁, and n₂ lies between 0.1 and 2.5.

7. An electroluminescence light source as claimed in claim 5, characterized in that the first material (9) is arranged in the second material (10), essentially in a periodic structure of a multiplicity of structural elements, in a plane parallel to the surface of the first light outcoupling layer(3), which structural elements are designed as spatial bodies, comprising spherical, cylindrical, pyramidal, cubical or ellipsoid bodies.

8. An electroluminescence light source as claimed in claim 7, characterized in that the structural elements, viewed in the direction of propagation of light, have a height H₁ and the thickness H₂ of the first light outcoupling layer (3) has a value between H₁ and 10*H₁.

9. An electroluminescence light source as claimed in claim 7 , characterized in that at a total number N of the structural elements, a distance aᵢ between two neighboring structural elements can deviate from an average distance a₀ and the distribution n(aᵢ) of the distances aᵢ fits the formula
$$n ( {a}_{i} ) = \frac{N}{{a}_{i} s \sqrt{2 π}} exp [ - \frac{{ln}^{2} ( {a}_{i} / {a}_{0} )}{2 {s}^{2}} ]$$
wherein 0<s<0.4.

10. An electroluminescence light source as claimed in claim 1, characterized in that the surface structure (8) of the second light outcoupling layer (1) comprises square pyramidal structures, triangular pyramidal structures, hexagonal pyramidal structures, ellipsoid dome structures or cone structures.

11. An electroluminescence light source as claimed in claim 1, characterized in that the height Hᵣ of the surface structure (8) of the second light outcoupling layer (1) in the direction of propagation of light (7) is larger than 10 μm and smaller than 5-fold the substrate thickness.

12. An electroluminescence light source as claimed in claim 1, characterized in that the second light outcoupling layer (1) has a refractive index larger than or equal to that of the substrate (2) and smaller than 3.
